(19) United States
(12) Patent Application Publication
(10) Pub. No.: US 2020/0307995 A1
(43) Pub. Date: Oct. 1, 2020

(54) Machine Learning Processor Employing a Monolithically Integrated Memory System

(71) Applicant: Vathys, Inc., Portland, OR (US)

(72) Inventor: Tapabrata Ghosh, Portland, OR (US)

(21) Appl. No.: 16/365,489

(22) Filed: Mar. 26, 2019

(51) Int. Cl. B82Y 10/00; G06N 3/06; G11C 13/02

(52) U.S. Cl. CPC B82Y 10/00; G06N 3/06; G11C 2213/16; G11C 2213/81; G11C 13/025

(57) ABSTRACT

Disclosed are systems and methods for monolithically-integrating an artificial intelligence processor system and a nanotube memory system on the same die to achieve high memory density and low power consumption.

### BACKGROUND

### Field of the Invention

This invention relates generally to the field of microprocessors and more particularly to processors optimized for handling artificial intelligence operations.

### Description of the Related Art

Processors using off-chip memory need to use wiring to transfer data to and from the off-chip memory circuits. Often, existing processor-memory configurations introduce technical challenges such as high power consumption and low bandwidth. In the context of processors used for handling artificial intelligence (AI) operations, the read and write operations to memory are more extensive than other applications. Consequently, inefficiencies associated with the processor accessing its memory system are more pronounced and problematic in the case of AI processors. Proposed are systems and methods for improved processor-memory combinations that can handle AI operations with more efficiency.

### SUMMARY

In one aspect of the invention, a machine learning processor system is disclosed. The system includes: one or more processor circuits optimized for handling machine learning operations; and a nanotube memory system configured to receive read and write operations of the one or more processor circuits.

In one embodiment, the processor circuits and the nanotube memory system are monolithically integrated on a same die.

In another embodiment, the nanotube memory system comprises CNT fabric-based resistance switching.

In some embodiments, the nanotube memory system comprises a cross-bar architecture or a 1 transistor-1 resistor (1T1R) architecture.

In one embodiment, the one or more processor circuits and the nanotube memory system are side-by-side on a substrate, or vertically stacked on a substrate, or a combination of side-by-side and vertically stacked relative to one another and relative to themselves.

In another embodiment, the nanotube memory system comprises homogenous memory cells made of carbon nanotubes.

In one embodiment, the nanotube memory system comprises heterogenous memory cells made of one or more of carbon nanotubes, gallium nitride nanotubes, and silicon nanotubes.

In one embodiment, one or more current sensing amplifiers are used to read from and/or write into cells of the nanotube memory system.

In some embodiments, the machine learning operations comprise one or more of: neural network, deep neural network, convolutional neural network (CNN), generating and/or processing activation functions, back-propagation, error minimization operations, statistical processing of data, inference using neural networks and training of neural networks.

In another embodiment, a computer system includes the machine learning processor.

In another aspect of the invention, a method is disclosed. The method includes: reading, from a nanotube memory system, data associated with a plurality of machine learning operations; performing, on a plurality of machine learning processors, a plurality of machine learning operations on the data; and writing in the nanotube memory system.

In one embodiment, the plurality of machine learning processors and the nanotube memory system are monolithically integrated on a same die.

In another embodiment, the nanotube memory system comprises CNT fabric-based resistance switching.

In one embodiment, the nanotube memory system comprises a cross-bar architecture or a 1 transistor-1 resistor (1T1R) architecture.

In another embodiment, the plurality of machine learning processors and the nanotube memory system are side-by-side on a substrate, or vertically stacked on a substrate, or a combination of side-by-side and vertically stacked relative to one another and relative to themselves.

In some embodiments, the nanotube memory system comprises homogenous memory cells made of carbon nanotubes.

In another embodiment, the nanotube memory system comprises heterogenous memory cells made of one or more of carbon nanotubes, gallium nitride nanotubes and silicon nanotubes.

In one embodiment, one or more current sensing amplifiers are used to read from and/or write into cells of the nanotube memory system.

In another embodiment, the machine learning operations comprise one or more of: neural network, deep neural network, convolutional neural network (CNN), generating and/or processing activation functions, back-propagation, error minimization operations, statistical processing of data, inference using neural networks and training of neural networks.

In one embodiment, a computer system is configured to perform the method.

### BRIEF DESCRIPTION OF THE DRAWINGS

These drawings and the associated description herein are provided to illustrate specific embodiments of the invention and are not intended to be limiting.

FIG. 1 illustrates a die where a processor and a nanotube memory system are integrated on the same wafer.

FIG. 2 illustrates an example nanotube memory system where nanotube cells are flanked by top and bottom electrodes.

FIG. 3 illustrates a diagram of a nanotube memory cell, utilizing a 1 transistor-1 resistor (1T1R) architecture, where a control transistor can be used in addition to a nanotube fabric region.

FIG. 4 illustrates an example of a monolithically-integrated memory system, where current sensing amplifiers can be used for read or write operations into nanotube memory cells.

### DETAILED DESCRIPTION

The following detailed description of certain embodiments presents various descriptions of specific embodiments of the invention. However, the invention can be embodied in a multitude of different ways as defined and covered by the claims. In this description, reference is made to the drawings where like reference numerals may indicate identical or functionally similar elements.

Unless defined otherwise, all terms used herein have the same meaning as are commonly understood by one of skill in the art to which this invention belongs. All patents, patent applications and publications referred to throughout the disclosure herein are incorporated by reference in their entirety. In the event that there is a plurality of definitions for a term herein, those in this section prevail. When the terms “one”, “a” or “an” are used in the disclosure, they mean “at least one” or “one or more”, unless otherwise indicated.

Recent microprocessors have explored the benefits of integrating memory chips and the processor circuits on the same wafer. For processors employing off-chip memory circuits, off-chip wiring is used to fetch and/or record data used by the processor. Compared to on-chip memory circuits, processors using off-chip memory consume higher energy, but offer lower bandwidth and transfer speeds. Machine learning processors can also benefit from on-chip memory circuits, such as static random-access memory (SRAM) and dynamic random-access memory (DRAM). Despite their promises, SRAM and DRAM can introduce their own issues such as low-density and high-power consumption (e.g. via leakage).

An alternative type of memory, utilizing nanotube elements (e.g., carbon nanotube (CNT) technology), promises improved characteristics compared to traditional memory circuits. For example, nanotube memories can be made much denser than their counterparts, therefore providing more memory functionality per unit of area. Unlike, some traditional memory arrays, nanotube memory arrays do not require refreshing and can maintain their charge state even after power is removed. Additionally, the power consumption of nanotube memories can be less than their counterparts as both read and write operations are of low-power.

These and other benefits of nanotube memories can be exploited in the context of machine learning processors. For example, nanotube memory arrays can be wired to one or more machine learning processors as off-chip memory circuits. While significant benefits can be realized from off-chip inclusion of the nanotube memories, some disadvantages can also be introduced. For example, power consumption within the wiring leading to the nanotube memories and within the arrays of the nanotube memory arrays can cancel some of the benefits of utilizing nanotube memories. Additionally, greater bandwidth across a single channel (e.g., a wire), beyond a threshold, can require exponentially more energy, thus creating another bottleneck limiting the performance of processors utilizing off-chip nanotube memories.

Integrating a nanotube memory system on the same wafer where the processor using the memory system is fabricated allows for manufacturing high-efficiency processors. Nanotube memory elements can be built from a variety of materials and technologies, such as carbon nanotubes (CNTs), gallium nitride (GaN) nanotubes, silicon nanotubes and other nanotube technology known to persons of ordinary skill in the art.

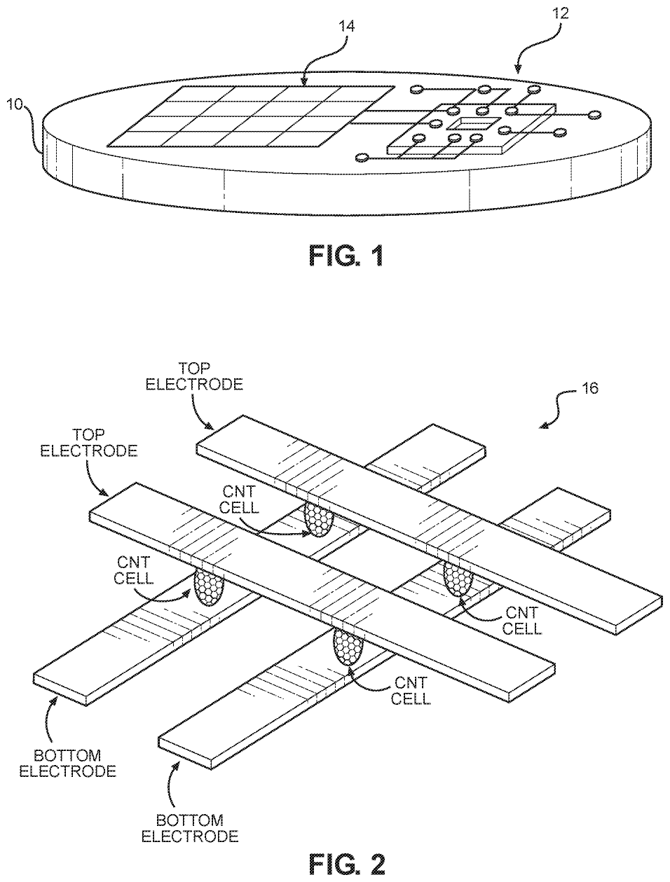

FIG. 1 illustrates a die 10 where a processor 12 and a nanotube memory system 14 are integrated on the same wafer. Significant advantages can be realized by the arrangement of FIG. 1 or other integration of processor and nanotube memory systems. In monolithically-integrated nanotube memory and processor systems such as those illustrated in FIG. 1, higher density memory (e.g. compared to SRAM) can be achieved. Additionally, the leakage in steady state can be substantially lower compared to traditional memories, thereby reducing overall power consumption of the monolithically-integrated device of FIG. 1.

While the nanotube memory system 14 and the processor 12 are shown in a side-by-side arrangement, other configurations are also possible. For example, one or more layers of processors and nanotube memories can be stacked vertically (3D integration) or fabricated side-by-side on the die 10. In other embodiments, wafer-scale-integration (WSI) method can be used where one or more nanotube memories and processors 12 can be integrated on the same die 10 and create a uniform computing system. In other embodiments, multiple copies of the same monolithically-integrated (on the same die) nanotube memory and processors can be fabricated on the die 10 and later sliced (diced) into individual processors with on-chip integrated nanotube memories. In each embodiment, the nanotube memories and processors can be a plurality of nanotube memory systems and/or processors fabricated side-by-side (horizontally) or stacked vertically with respect to each other.

Processor or processors 12 can include any type of processor that can interface with a memory system 14 to perform one or more computing functions, such as logic calculations or other processor operations. The processor 12 can be a machine learning processor optimized for handling and/or accelerating machine learning operations, such as neural network, deep neural network, convolutional neural network (CNN), generating and/or processing activation functions, back-propagation, error minimization operations, statistical processing of data, inference using neural networks and training of neural networks and/or other artificial intelligence (AI) operations.

Example machine processors utilize high parallelism in task or data to accelerate the processing and execution of their underlying tasks. They perform vector, matrix, nd-array, tensor and/or other data structures operations in a data-flow architecture. Some machine learning processors utilize arithmetic logic units (ALUs) with 32 bits or less of precision, which can be floating point or integer. Machine learning processors often perform forward processing of data and backward passing and processing of data (e.g., in training accelerators) through neural networks or other AI processing schemes.

The memory system 14 can include a nanotube memory (e.g., a CNT memory array), nano random-access memory (NRAM), CNT fabric-based resistance switching memory and other memories utilizing CNTs or nanotube technologies (such as gallium nitride nanotubes, silicon nanotubes, etc.).

FIG. 2 illustrates an example nanotube memory system 16 where CNT cells are flanked by top and bottom electrodes. While CNT cells are shown, other nanotube technologies can also be used. Examples include gallium nitride nanotubes (GaNNTs), silicon nanotubes and other nanotube technologies known to persons of ordinary skill in the art. The nanotube memory system 16 can be considered a cross-type architecture, where CNT fabric regions are deposited, grown, or otherwise placed at the intersection of electrode lines. The top and bottom electrodes can be electrically connected to control circuits and/or power supply lines (not shown) and/or route to and be electrically connected to the processor 12 to act as the memory system of the processor 12.

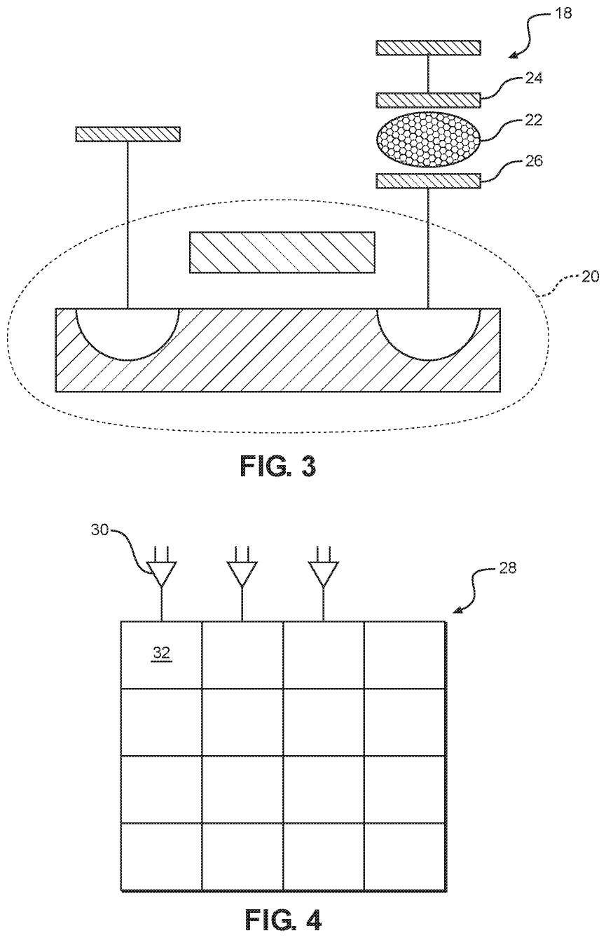

FIG. 3 illustrates a diagram of a nanotube memory cell 18, utilizing a 1 transistor-1 resistor (1T1R) architecture, where a control transistor can be used in addition to a nanotube fabric region. The nanotube memory cell 18 includes a control transistor 20, including gate, drain and source regions if a metal-oxide semiconductor field-effect transistor (MOSFET) is used. Other types of transistors such as bipolar junction transistors (BJTs) can also be used. The nanotube fabric region 22 is flanked between a top electrode 24 and bottom electrode 26. The nanotube fabric region 22 can be made of CNTs, GaNNTs, silicon nanotubes and/or other nanotube technology known to persons of ordinary skill in the art.

The nanotube fabric regions 22 (and those shown in FIG. 2) can be substantially homogenous or substantially or partially heterogenous nanotube fabric regions where one or more layers can be different in mechanical, material and/or electrical characteristics. For example, one layer may be made of gallium nitride nanotubes (GaNNTs), while other layers can be made of carbon nanotubes (CNTs). Similarly, silicon nanotubes or other nanotube technologies known to persons of ordinary skill in the art can be used. In another example, one layer maybe a multi-walled nanotube while other layers may be single-walled nanotubes.

FIG. 4 illustrates an example of a monolithically-integrated memory system 28, where current sensing amplifiers 30 can be used for read or write operations into nanotube memory cells 32. Unlike SRAM and DRAM memory cells, the read and write operations of the nanotube memory cells are somewhat DC rather than AC.

Using nanotube memory systems on the same die as the processor using the memory system allows for much higher density than conventional memories such as SRAM. In addition, the inclusion of nanotube memory on the same die as the processor allows reduction in leakage which can significantly reduce the on-chip static power consumption, thereby allowing for a more efficient processor.

While some nanotube memory system architectures and types are herein described as examples, the disclosed embodiments are not limited to those examples and architectures. Persons of ordinary skill in the art can envision other nanotube memory system types and architectures which can be monolithically-integrated with machine learning or other processors according to the described embodiments.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first, second, other and another and the like may be used solely to distinguish one entity or action from another without necessarily requiring or implying any actual such relationship or order between such entities or actions.

The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various implementations. This is for purposes of streamlining the disclosure and is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the Detailed Description, with each claim standing on its own as a separately claimed subject matter.

What is claimed is:

1. A machine learning processor system comprising:
one or more processor circuits optimized for handling machine learning operations; and
a nanotube memory system configured to receive read and write operations of the one or more processor circuits.

2. The system of claim 1, wherein the processor circuits and the nanotube memory system are monolithically integrated on a same die.

3. The system of claim 1, wherein the nanotube memory system comprises CNT fabric-based resistance switching.

4. The system of claim 1, wherein the nanotube memory system comprises a cross-bar architecture or a 1 transistor-1 resistor (1T1R) architecture.

5. The system of claim 1, wherein the one or more processor circuits and the nanotube memory system are side-by-side on a substrate, or vertically stacked on a substrate, or a combination of side-by-side and vertically stacked relative to one another and relative to themselves.

6. The system of claim 1, wherein the nanotube memory system comprises homogenous memory cells made of carbon nanotubes.

7. The system of claim 1, wherein the nanotube memory system comprises heterogenous memory cells made of one or more of carbon nanotubes, gallium nitride nanotubes, and silicon nanotubes.

8. The system of claim 1, wherein one or more current sensing amplifiers are used to read from and/or write into cells of the nanotube memory system.

9. The system of claim 1, wherein the machine learning operations comprise one or more of: neural network, deep neural network, convolutional neural network (CNN), generating and/or processing activation functions, back-propagation, error minimization operations, statistical processing of data, inference using neural networks and training of neural networks.

10. A computer system comprising the machine learning processor system of claim 1.

11. A method comprising:
reading, from a nanotube memory system, data associated with a plurality of machine learning operations;
performing, on a plurality of machine learning processors, a plurality of machine learning operations on the data; and
writing in the nanotube memory system.

12. The method of claim 11, wherein the plurality of machine learning processors and the nanotube memory system are monolithically integrated on a same die.

13. The method of claim 11, wherein the nanotube memory system comprises CNT fabric-based resistance switching.

14. The method of claim 11, wherein the nanotube memory system comprises a cross-bar architecture or a 1 transistor-1 resistor (1T1R) architecture.

15. The method of claim 11, wherein the plurality of machine learning processors and the nanotube memory system are side-by-side on a substrate, or vertically stacked on a substrate, or a combination of side-by-side and vertically stacked relative to one another and relative to themselves.

16. The method of claim 11, wherein the nanotube memory system comprises homogenous memory cells made of carbon nanotubes.

17. The method of claim 11, wherein the nanotube memory system comprises heterogenous memory cells made of one or more of carbon nanotubes, gallium nitride nanotubes and silicon nanotubes.

18. The method of claim 11, wherein one or more current sensing amplifiers are used to read from and/or write into cells of the nanotube memory system.

19. The method of claim 11, wherein the machine learning operations comprise one or more of: neural network, deep neural network, convolutional neural network (CNN), generating and/or processing activation functions, back-propagation, error minimization operations, statistical processing of data, inference using neural networks and training of neural networks.

20. A computer system configured to perform the method of claim 11.
